(19) United States
(12) Patent Application Publication
(10) Pub. No.: US 2001/0000629 A1
(43) Pub. Date: May 3, 2001

(54) Semiconductor device and process of producing the same

(75) Inventor: Masanori Tsukamoto, Kanawaga (JP)

Correspondence Address: David R. Metzger, Esq., SONNENSCHEIN NATH & ROSENTHAL, P.O. Box #061080, Wacker Drive Station, Sears Tower, Chicago, IL, 60606-1080, US

(73) Assignee: Sony Corporation

(21) Appl. No.: 09/731,195

(22) Filed: Dec. 6, 2000

Related U.S. Application Data
(62) Division of application No. 09/289,543, filed on Apr. 12, 1999.

(30) Foreign Application Priority Data
Apr. 15, 1998 (JP) P10-102929

(51) Int. Cl. H01L 21/336; H01L 21/8234; H01L 21/3205; H01L 21/4763; H01L 31/119; H01L 29/76; H01L 31/113

(52) U.S. Cl. 257/388; 438/592; 438/585

(57) ABSTRACT

A semiconductor device, in which diffusion of impurities and boron penetration are prevented, comprising a substrate, a first polycrystalline silicon layer formed on the substrate and comprising large grain polycrystalline silicon with a maximum grain size of more than 200 nm; a second polycrystalline silicon layer formed on the first polycrystalline silicon layer and comprising large grain polycrystalline silicon with a maximum grain size of at least 200 nm; and a metal layer or a metal silicide layer formed on the second polycrystalline silicon layer.

### BACKGROUND OF THE INVENTION

1. 1. Field of the Invention

2. The present invention relates to a semiconductor device having interconnections of a metal silicide on polycrystalline silicon (polycide) structure or interconnections of a metal on polycrystalline silicon structure and a process of production of the same, more particularly relates to a semiconductor device which suppresses the fluctuation in characteristics in a MOSFET due to the diffusion of impurities of different conductivities into the interconnection layer and the “penetration” of boron, that is, the diffusion through the gate oxide film to the substrate, and a process of production of the same.

3. 2. Description of the Related Art

4. Complementary metal oxide semiconductor devices (CMOS), consisting of n-channel metal oxide semiconductor (MOS) field effect transistors (FET) (NMOS) and a p-channel MOSFETs (PMOS), have the advantages of a low power consumption and a high speed and therefore are being widely used as memories, logics, and other devices in many large-scale integrated circuits (LSI). Along with the advances made in integration of LSIs, the gate lengths in the FETs have been shortened.

5. In the past, in order to simplify the process or to make a buried-channel type device so as to reduce the phase boundary potential and raise the electron mobility, the gate electrodes in a PMOSFET have been made of n-type polycrystalline silicon doped with a large amount of phosphorus in the same way as in the NMOSFET.

6. However, in the deep sub-micron generation and on, it is difficult to prevent the short channel effect in a buried-channel type device. It would be more effective to use a surface-channel type device having p⁺-type gates (for example, see Japanese Unexamined Patent Publication (Kokai) No. 6-310666).

7. To form different conductivity gates, that is, to form an n⁺-type gate in the NMOS and form a p⁺-type gate in the PMOS, arsenic (As) or phosphor (P) ions are implanted in the polycrystalline silicon of the gate electrode for the n-type and boron (B) ions are implanted for the p-type.

8. However, when using interconnections of a metal silicide on polycrystalline silicon (polycide) structure or interconnections of a metal on polycrystalline silicon structure for the gate electrodes, since the diffusion rate of the impurities in metal silicide is much faster than that in silicon or silicon oxide (about 10⁴ in terms of the diffusion coefficient), the n-type and p-type impurities diffuse in each other. Therefore, the arsenic (As) or phosphorus (P) introduced into the m-type gate electrode forming regions and the boron (B) introduced into the p-type gate electrode forming regions work against each other.

9. This phenomenon causes fluctuation in the Fermi-level in the polycrystalline silicon and depletion in the gate electrode and fluctuation in the threshold voltage (Vₜₕ) when the gate voltage is supplied and consequently a decline of performance in the device. In the case of a p⁺-type gate, the boron diffuses through the gate oxide film and reaches the substrate resulting in fluctuation of the threshold voltage Vₜₕ in the MOSFET and a fall in the reliability of the gate oxide film. Particularly, it is known that the inclusion of fluorine (F) in the polycrystalline silicon or gate oxide film causes an increase in the diffusion rate of boron. Therefore it is required to optimize the gate structure and method of formation in order to prevent fluorine from diffusing into the polycrystalline silicon or gate oxide film.

10. On the other hand, in the formation of a MOSLSI, a SALICIDE process is often adopted in which silicide is formed by self-alignment on the gate polycrystalline silicon after the formation of the MOSFET. Since the problem of mutual diffusion of impurities is solved according to the SALICIDE process, the SALICIDE structure is suitable for forming a dual gate structure.

11. A process has been proposed for making the gate polycrystalline silicon in a SALICIDE structure a double layer structure and making both layers large grain polycrystalline silicon (“Gate Electrode Microstructure” in IEDM Tech. Dig. (1997) p. 635). This suppresses boron penetration.

12. In the SALICIDE process, however, it is known that TiSi₂ or CoSi₂ increase in resistance upon heat treatment at 800° C. or higher and that, in particular, the resistance remarkably increases in the narrow interconnection regions. Therefore it is difficult to apply the SALICIDE process for the process of formation of a memory, requiring a high temperature process after the formation of the MOSFET, or the process of formation of a combination memory and logic. It is necessary to use a highly heat-resistant interconnection structure such as a polycide structure comprised of a tungsten or other refractory metal silicide on polycrystalline silicon.

13. The conventional structure of a dual gate CMOS will be explained next referring to FIG. 7. In a tungsten polycide structure comprised of a polycrystalline silicon layer 24 and tungsten silicide layer (WSiₓ) 25, an n-type impurity such as phosphorus is diffused in the NMOS polycrystalline silicon and a p-type impurity such as boron is diffused in the PMOS polycrystalline silicon.

14. Summarizing the problem to be solved by the invention, as shown in FIG. 7, if performing annealing for activation of an impurity or another high temperature heat treatment, the phosphorus diffuses through the tungsten silicide layer 25 and migrates to the p-type polycrystalline silicon. Consequently, the Fermi-level in the polycrystalline silicon in the gate electrode fluctuates or the gate electrode becomes depleted at the time of application of the gate voltage and the threshold voltage Vₜₕ fluctuates causing a fall in the properties of the MOSFET.

15. When the tungsten silicide layer 25 contains fluorine, the fluorine diffuses through the crystal boundaries of the polycrystalline silicon and reach the gate oxide film 23 causing penetration of boron into the substrate 21.

16. To solve the above problem, the method has been proposed of the use of large grain polycrystalline silicon as the polycrystalline silicon layer (“Improving Gate Oxide” in IEDM Tech. Dig. (1993) p. 471). According to this method, it is considered possible to reduce the crystal boundaries to suppress diffusion of fluorine and other impurities.

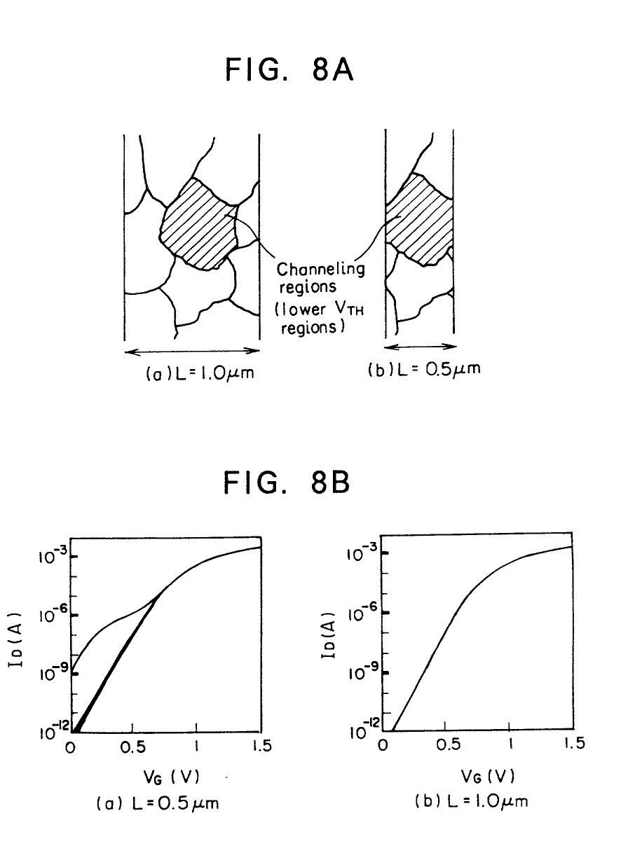

17. When using large grain polycrystalline silicon in a single layer for a gate electrode, however, it has been reported that, as shown in FIG. 8, the crystal boundaries are formed unevenly on the MOSFET channel region resulting in fluctuation in the MOSFET properties (“Gate Electrode Microstructure” in IEDM Tech. Dig. (1997) p. 635).

18. FIG. 8A is a view of the cross-sectional structure of a gate electrode comprised of large grain polycrystalline silicon (LGP). For example, compared with a case of a gate length of 1.0 μm of (a), in the case of a gate length of 0.5 μm of (b), a bamboo structure results. Therefore, in a LGP gate electrode, if the gate length becomes shorter, the fluctuation in the MOSFET properties becomes remarkable.

19. FIG. 8B is a view of the sub-threshold characteristic (gate voltage V_{G} (V)—drain current I_{D} (A)) of an nMOSFET having a gate electrode of a single layer of LGP. The drain current when a voltage near the threshold voltage or less is applied to the gate electrode, that is, the drain current in the sub-threshold region, increases exponentially when the gate voltage is increased. In the case of a gate length of 1.0 μm of (b), the sub-threshold characteristic is good, but in the case of a gate length of 0.5 μm of (a), the inclination of the gate voltage V_{G} (V)—drain current I_{D} (A) becomes smaller locally—which obstructs high-speed, low power consumption switching.

20. However, even when using LGP for the gate electrode, the fluctuation in the MOSFET characteristics is suppressed by use of a double layer (two-layer) structure.

21. Methods of making the polycrystalline silicon layer a two-layer structure with a lower layer of ordinary polycrystalline silicon (“as-deposited” polysilicon, crystallized at the point of deposition) and with an upper layer of large grain polycrystalline silicon have been proposed by the inventors (Japanese Unexamined Patent Publication (Kokai) No. 9-186246 and Japanese Unexamined Patent Publication (Kokai) No. 10-12744). With the above methods, however, polycrystalline silicon is deposited at the lower layer and amorphous silicon at the upper layer, therefore the film deposition temperature and other film-forming conditions differ and it is necessary to use separate CVD systems to form the silicon films—which is not preferable from the viewpoint of the productivity.

### SUMMARY OF THE INVENTION

22. An object of the present invention is to provide a semiconductor device having interconnections of a metal silicide on at least two layers of polycrystalline silicon (polycide) structure or interconnections of a metal on at least two layers of polycrystalline silicon structure and a process of production of the same, more particularly a semiconductor device which suppresses having interconnections of a metal silicide on polycrystalline silicon (polycide) structure or interconnections of a metal on polycrystalline silicon structure and a process of production of the same, more particularly relates to a semiconductor device which suppresses the fluctuation in characteristics in a MOSFET due to the diffusion of impurities of different conductivities into the interconnection layer and the “penetration” of boron in a dual gate CMOS and a process of production of the same.

23. According to a first aspect of the present invention, there is provided a semiconductor device comprising a substrate; a first polycrystalline silicon layer, formed on the substrate, comprising large grain polycrystalline silicon with a maximum crystal grain size of at least 200 nm; a second polycrystalline silicon layer, formed on the first polycrystalline silicon layer, comprising large grain polycrystalline silicon with a maximum crystal grain size of at least 200 nm; and one of a metal layer and a metal silicide layer formed on the second polycrystalline silicon layer.

24. Preferably, the semiconductor device further comprises an interlayer film formed between the first polycrystalline silicon layer and the second polycrystalline silicon layer at a thickness within a range that allows electrical passage of electrons in the first and second polycrystalline silicon layers by direct tunneling.

25. Preferably, the interlayer film comprises silicon oxide and the thickness is not more than 2 nm.

26. More preferably, the metal silicide layer comprises tungsten silicide.

27. By forming the first and the second polycrystalline silicon layers by large grain polycrystalline silicon with a maximum crystal grain size of at least 200 nm in interconnections of a metal silicide on polycrystalline silicon (polycide) structure or of a metal on polycrystalline silicon structure where the polycrystalline silicon layer is comprised of at least two layers, it is possible to form a polycrystalline silicon layer with little crystal boundaries. Due to this, it is possible to suppress the diffusion of conductive impurities diffusing in the metal or metal silicide layer from diffusing into the other conductivity type regions of the polycrystalline silicon.

28. Due to this, diffusion of fluorine into the gate oxide film is suppressed. On the other hand, it is known that the diffusion rate of boron increases due to the presence of fluorine. According to the semiconductor device of the present invention, since fluorine diffusion is suppressed, the diffusion rate of boron can be suppressed. Therefore, the fluctuation of the threshold voltage Vₜₕ due to boron penetration can be suppressed.

29. According to a second aspect of the present invention, there is provided a process of production of a semiconductor device comprising the steps of forming a first amorphous silicon layer on a substrate; forming a second amorphous silicon layer on the first amorphous silicon layer; doping different conductivities of impurities at predetermined intervals into both the amorphous silicon layers; applying a high temperature heat treatment to make the impurities diffuse into the amorphous silicon layers and crystallize the amorphous silicon layers to form polycrystalline silicon layers; and forming one of a metal layer and metal silicide layer on the polycrystalline silicon layers.

30. Preferably, the polycrystalline silicon layers formed by the crystallization of the first and the second amorphous silicon layers comprise large grain polycrystalline silicon with a maximum crystal grain size of at least 200 nm.

31. Preferably, the first amorphous silicon layer and the second amorphous silicon layer are formed using the same chemical vapor deposition (CVD) system.

32. Preferably, the process of production of a semiconductor device further comprises forming an interlayer film between the first amorphous silicon layer and the second amorphous silicon layer with a thickness in a range that allows electrical passage of electrons in the polycrystalline silicon layers by direct tunneling.

33. More preferably, the interlayer film comprises silicon oxide and the thickness is not more than 2 nm.

34. Still more preferably, the interlayer film is formed by oxidizing the surface of the first amorphous silicon layer by washing with at least one of mixed solutions selected from the group of a mixed solution of hydrogen peroxide and hydrofluoric acid, a mixed solution of hydrogen peroxide and sulfuric acid, a mixed solution of hydrogen peroxide and ammonia, and a mixed solution of hydrogen peroxide and hydrochloric acid.

35. Alternatively, still more preferably, the interlayer film is formed by thermal oxidation of the surface of the first amorphous silicon layer.

36. Alternatively, still more preferably, the interlayer film is formed by deposition of silicon oxide on the surface of the first amorphous silicon layer.

37. Preferably, the metal silicide layer comprises tungsten silicide.

38. Due to this, when forming two or more layers of polycrystalline silicon, since it is possible, even when different impurities are to be doped into the polycrystalline silicon layers, to use the same CVD system to deposit silicon layers as amorphous silicon layers, it is possible to improve the productivity.

39. Further, according to the process of production of a semiconductor device of the present invention, the method may be applied for forming polycrystalline silicon layers containing different types of conductive impurities.

40. Forming polycrystalline silicon layers by crystallizing the amorphous silicon to make polycrystalline silicon layers, it is possible to form polycrystalline silicon layers with a maximum crystal grain size of about 200 nm or more—larger than the crystal grain size of polycrystalline silicon layers formed by the CVD method. Due to this, the crystal boundaries are decreased and it is possible to suppress the impurities diffusing in the metal or metal silicide layer from diffusing into the polycrystalline silicon.

41. Moreover, by having the first and the second polycrystalline silicon layers be formed by large grain polycrystalline silicon, continuous crystal growth between the first polycrystalline silicon layer and the second polycrystalline silicon layer can be suppressed during the crystallization of the two layers of polycrystalline silicon (formation of large grains). Therefore, it is possible to suppress fluctuations in the MOSFET characteristics due to unevenness in crystal boundaries.

42. After the first amorphous silicon is deposited, an oxide film (SiOₓ) of a thickness of about 2 nm or less is formed on the amorphous silicon. Therefore, when crystallizing the amorphous silicon, the effect of the state of crystallization of the underlying first silicon layer on the second amorphous silicon layer is reduced and it becomes possible to form the second amorphous silicon layer into a large grain polycrystalline silicon layer. Due to this, it becomes possible to suppress fluctuations in the threshold voltage Vₜₕ caused by mutual diffusion of impurities.

43. The oxide film (SiOₓ) can be formed by washing the surface with an acidic solution containing hydrogen peroxide, by thermal oxidation, by deposition of an oxide film, or another method. In particular, by treatment with mixed solutions of hydrogen peroxide, hydrofluoric acid, sulfuric acid, ammonia, or hydrochloric acid or aqueous solutions of the same, it is possible to form a SiOₓ film with a thickness of not more than 2 nm with good control. Due to this, it is possible to suppress continuous crystal growth during the crystallization of the two layers of polycrystalline silicon (formation of large grains).

44. By using tungsten silicide (WSiₓ) as the metal silicide, it is possible to form a gate electrode with a high heat resistance and a low electric resistance. Therefore, it is possible to use a dual gate for a memory or a combination memory and logic.

45. As the metal silicide, other than tungsten silicide, it is possible to use for example molybdenum silicide, titanium silicide, tantalum silicide, palladium silicide, etc. Particularly, it is preferable to use tungsten silicide, which is superior in formability, in suppressing the narrow interconnection effect such as with a SALICIDE process.

### BRIEF DESCRIPTION OF THE DRAWINGS

46. These and other objects and features of the present invention will become clearer from the following description of the preferred embodiments given with reference to the accompanying drawings, in which:

47. FIG. 1 is a cross-sectional view of a semiconductor device of the present invention;

48. FIG. 2 is a cross-sectional view of a step of the process of production of the semiconductor device of the present invention;

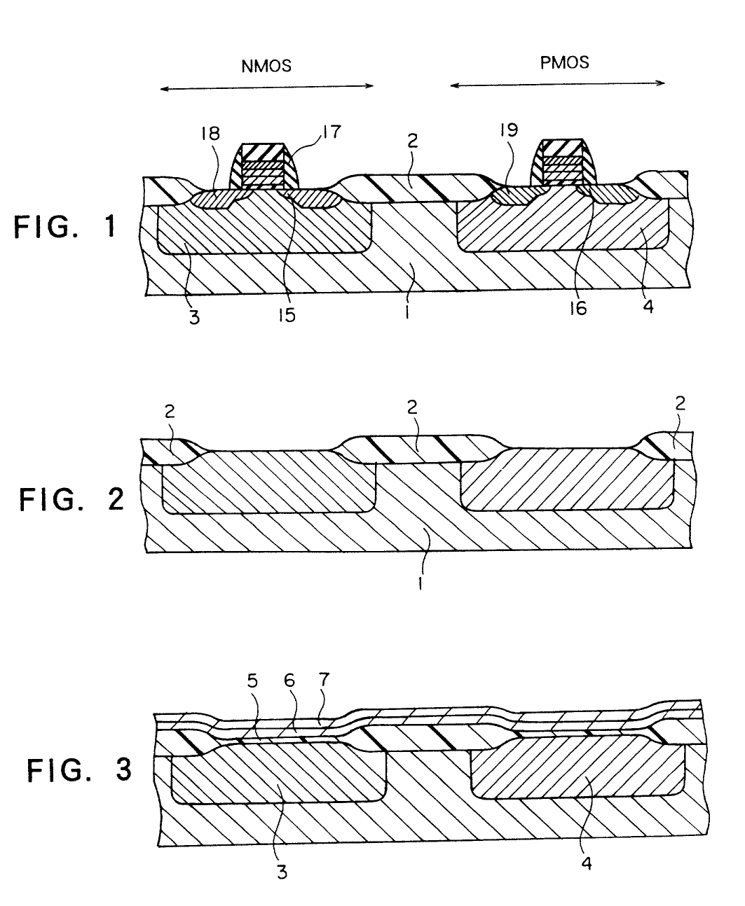

49. FIG. 3 is a cross-sectional view of another step of the process of production of the semiconductor device of the present invention;

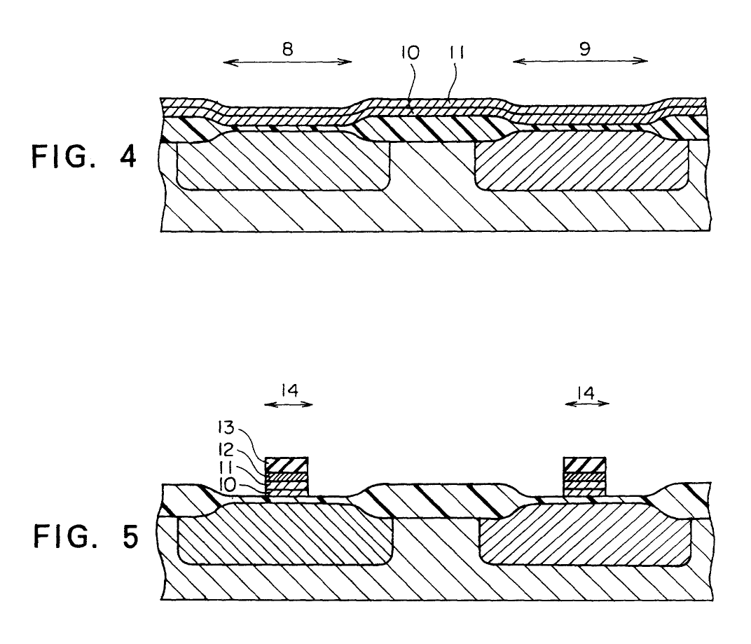

50. FIG. 4 is a cross-sectional view of another step of the process of production of the semiconductor device of the present invention;

51. FIG. 5 is a cross-sectional view of another step of the process of production of the semiconductor device of the present invention;

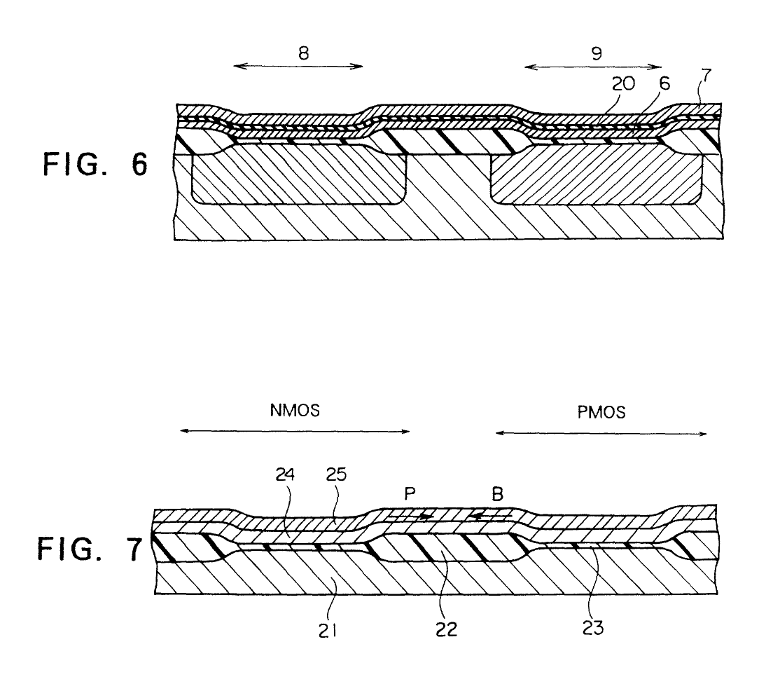

52. FIG. 6 is a cross-sectional view of another step of the process of production of the semiconductor device of the present invention;

53. FIG. 7 is a cross-sectional view of a semiconductor device of the related art; and

54. FIGS. 8A and 8B are figures showing the fluctuation in MOSFET characteristics caused by the unevenness of crystal boundaries.

### DESCRIPTION OF THE PREFERRED EMBODIMENTS

55. Below, an explanation will be made of preferred embodiments of the present invention with reference to the drawings.

56. First Embodiment

57. FIG. 1 is a sectional view of a semiconductor device according to a first embodiment of the present invention.

58. In FIG. 1, a p-well 3 and an n-well 4 formed in a silicon substrate 1 are separated by an element isolation layer (LOCOS) 2. Each well is formed with a gate electrode consisting of a gate oxide film 15, two amorphous silicon layers, and a tungsten silicide layer. An inter-layer insulating film is formed at the top layer.

59. Next, an explanation will be made of the process of production of a semiconductor device according to the present embodiment.

60. First, as shown in FIG. 2, a field oxide film 2 is formed on the silicon substrate 1 by the LOCOS process (for example, wet oxidation at 950° C.).

61. Next, a dopant is introduced in the region for forming the NMOSFET for forming a p-well and a buried layer designed to prevent punch-through. Thus, the p-well 3 is formed. Similarly, a dopant is introduced in the region for forming the PMOSFET for forming an n-well and a buried layer designed to prevent punch-through. Thus, the n-well 4 is formed.

62. Next, as shown in FIG. 3, the gate oxide film 5 is formed at a thickness of about 5 nm by pyrogenic oxidation (H₂/O₂, 850° C.).

63. Amorphous silicon is deposited to a thickness of 70 nm by a low pressure CVD process (for example, using SiH₄ as a material gas and a deposition temperature of 550° C.) to form the first amorphous silicon layer 6.

64. Next, a natural oxide film formed on the surface of the first amorphous silicon layer 6 is removed using a hydrofluoric acid solution, then pressure CVD is performed again under the same conditions as the formation of the first amorphous silicon layer to deposit amorphous silicon to a thickness of 70 nm and form the second amorphous silicon layer 7.

65. Here, after the natural oxide film is removed by the hydrofluoric acid solution, the substrate in the CVD chamber is exposed to the atmosphere before forming the second amorphous silicon layer 7 so as form an ultra-thin natural oxide film on the surface of the amorphous silicon layer. This ultra-thin oxide film inhibits continuous crystal growth during crystallization of the two layers of amorphous silicon (formation of large grains).

66. Next, using a resist (not shown) patterned by photolithography as a mask, phosphorus (P) ions are implanted in only the region forming the NMOSFET to form the n⁺-gate region 8 shown in FIG. 4. The ion implantation is performed under conditions for example of 10 keV and 5×10¹⁵/cm².

67. In the same way, using a resist (not shown) patterned by photolithography as a mask, boron (B) ions are implanted in only the region forming the PMOSFET under conditions for example of 5 keV and 5×10¹⁵/cm² to form a p⁺-gate region 9.

68. This results in the structure shown in FIG. 4.

69. Next, annealing is performed at 650° C. for 10 hours in a nitrogen atmosphere to crystallize the amorphous silicon layers 6 and 7. The top layer second amorphous silicon layer 7 therefore becomes a larger grain polycrystalline silicon than the lower layer first polycrystalline silicon layer 6. Due to this, the polycrystalline silicon layers 10, 11 are formed.

70. Next, rapid thermal annealing (RTA) is performed at 1000° C. for 10 seconds to cause the n⁺- and p⁺-impurities to diffuse into polycrystalline silicon.

71. Next, low pressure CVD (using WF₆/SiH₄ as a material gas and a deposition temperature of 380° C., for example) is used to deposit a tungsten silicide layer 12 at a thickness of 70 nm, then CVD (using SiH₄/O₂ as a material gas and a deposition temperature of 420° C., for example) is used to deposit on this SiO₂at a thickness of 150 nm to form an offset oxide film 13.

72. The resist is patterned by photolithography, then anisotropic etching is performed using the resist as a mask so as to form the pattern of gate electrodes. The etching may be performed using as an etching gas a fluorocarbon based gas in the case of SiO₂ and Cl₂/O₂ in the case of tungsten silicide layer. This results in the structure shown in FIG. 5.

73. Next, As⁺ions, for example, are implanted in the p-well 3 under conditions of 20 keV and 5×10¹³/cm² to form an n-lightly doped drain (LDD) region 15. Further, BF₂⁺ions, for example, are implanted in the n-well 4 under conditions of 20 keV and 2×10¹³/cm² to form a p-LDD region 16.

74. Next, low pressure CVD is used to deposit SiO₂ over the entire surface to a thickness of 150 nm, then anisotropic etching is performed to form a sidewall 17.

75. Next, As⁺ions, for example, are implanted in the NMOS to form an n-type source/drain region 18. The ions are implanted under conditions of for example 20 keV and 3×10¹⁵/cm². BF₂⁺ions, for example, are implanted in the PMOS to form a p-type source/drain region 19. The ions are implanted under conditions of for example 20 keV and 3×10¹⁵/cm².

76. Next, the impurities are activated under RTA (1000° C., 10 seconds) conditions to form the CMOSFET.

77. Due to this, the semiconductor device shown in FIG. 1 results.

78. According to the semiconductor device of the present embodiment, by making the n⁺/p⁺impurities diffuse into the polycrystalline silicon before the tungsten silicide is deposited and growing large grain polycrystalline silicon, it is possible to suppress mutual diffusion of n⁺/p⁺impurities and to boron penetration to the substrate.

### Second Embodiment

79. In the semiconductor device of the above first embodiment, the ultra-thin natural oxide film formed between at the polycrystalline silicon interface was formed exposing the substrate in the CVD chamber to the atmosphere. Therefore, formation of completely uniform natural oxide layer was difficult. Continuous crystal growth occurred at the polycrystalline silicon interface resulting in insufficiently large crystal grain size and the unevenness of the crystal boundaries resulted in fluctuations in the MOSFET characteristics.

80. The second embodiment is an example of reduction of the unevenness of crystal boundaries at the polycrystalline silicon interface as seen in the above first embodiment by the formation of an oxide film (SiO₂) at the polycrystalline silicon interface.

81. First, as shown in FIG. 2, in the same way as the first embodiment, a field oxide film 2 is formed on the silicon substrate 1 by the LOCOS process (such as wet oxidation at 950° C.). Next, a dopant is introduced in the region to form the NMOSFET forming a p-well or a buried layer designed to prevent punch-through. Due to this, the p-well 3 is formed. Similarly, a dopant is introduced in the PMOSFET region for forming an n-well or a buried layer designed to prevent punch-through. Due to this, the n-well 4 is formed.

82. Next, as shown in FIG. 3, a gate oxide film 5 is formed at a thickness of about 5 nm by pyrogenic oxidation (H₂/O₂, 850° C.).

83. Amorphous silicon is deposited to a thickness of 70 nm by low pressure CVD (for example, using SiH₄ as a material gas and a deposition temperature of 550° C.) to form the first amorphous silicon layer 6.

84. Next, as shown in FIG. 6, the first amorphous silicon layer 6 is treated with a mixed solution of hydrochloric acid and hydrogen peroxide to form a thin oxide film 20 to a thickness of about 1 nm. Further, amorphous silicon is deposited to a thickness of 70 nm by low pressure CVD (for example, using SiH₄ as a material gas and a deposition temperature of 550° C.) to form the second amorphous silicon layer 7. Next, as shown in FIG. 6, in the same way as the first embodiment, an n⁺-gate region and p⁺-gate region are formed.

85. Next, as shown in FIG. 5, a tungsten silicide layer 12 and an offset oxide film 13 are stacked and then anisotropic etching is carried out to pattern the gate electrodes.

86. Further, As⁺ions, for example, are implanted in the p-well 3 to form an n-type LDD 15 and BF₂⁺ions, for example, are implanted in the n-well 4 to form a p-type LDD 16. Next, As⁺ions, for example, are implanted in the p-well 3 to form an n-type source/drain 18 and BF₂⁺ions, for example, are implanted in the n-well 4 to form a p-type LDD 16.

87. RTA is performed in the same way as the first embodiment to form the CMOSFET.

88. According to the semiconductor device of the present embodiment, by forming a silicon oxide film of not more than 2 nm before depositing the upper layer amorphous silicon layer, it is possible to increase the grain size during crystallization of the upper layer amorphous silicon layer.

89. When crystallizing the amorphous silicon by low temperature, long term annealing (650° C., 10 hours for example), it is possible to form larger grain crystalline silicon the slower the nucleus generating rate.

90. According to the present embodiment, further, a uniform, thin oxide film is formed at a layer above the lower layer amorphous silicon (or polycrystalline silicon). Therefore, during the crystallization of the upper layer amorphous silicon layer, nuclei are randomly formed on the thin oxide film without being affected by the state of crystallization of the lower layer silicon.

91. Consequently, it becomes possible to crystallize the upper layer amorphous silicon layer independently from the lower layer polycrystalline silicon. Further, by randomly forming nuclei on the thin oxide film, it is possible to obtain large grain polycrystalline silicon.

92. The semiconductor device and process of production of the present invention are not limited to the above embodiments. For example, in the second embodiment, the interlayer insulating film between the first polycrystalline silicon layer and the second polycrystalline silicon layer was formed by treatment by a mixed solution of hydrochloric acid and hydrogen peroxide, but it is also possible to change this to acids other than hydrochloric acid.

93. In addition, various modifications may be made within a range not outside the gist of the present invention.

94. Summarizing the effects of the present invention, according to the semiconductor device of the present invention, by using a two-layer structure of polycrystalline silicon and forming large grain polycrystalline silicon, it is possible to suppress boron penetration into the substrate due to the effect of diffusion of fluorine and the fluctuation in the threshold voltage Vₜₕ due to the mutual diffusion of n⁺-/p⁺-type impurities.

95. Further, according to the process of production of a semiconductor device of the present invention, two or more layers of amorphous silicon are formed in the same CVD system under the same conditions. Therefore, it is possible to improve the productivity. According to the semiconductor device of the present invention, by forming a oxide film between the amorphous silicon layers, it is possible to crystallize the first and second amorphous silicon into large grain polycrystalline silicon.

What is claimed is:

1. A semiconductor device comprising:
a substrate;
a first polycrystalline silicon layer, formed on the substrate, comprising large grain polycrystalline silicon with a maximum crystal grain size of at least 200 nm;
a second polycrystalline silicon layer, formed on the first polycrystalline silicon layer, comprising large grain polycrystalline silicon with a maximum crystal grain size of at least 200 nm; and
one of a metal layer and a metal silicide layer formed on the second polycrystalline silicon layer.

2. A semiconductor device as set forth in claim 1, further comprising an interlayer film formed between the first polycrystalline silicon layer and the second polycrystalline silicon layer at a thickness within a range that allows electrical passage of electrons in the first and second polycrystalline silicon layers by direct tunneling.

3. A semiconductor device as set forth in claim 2, wherein the interlayer film comprises silicon oxide and the thickness is not more than 2 nm.

4. A semiconductor device as set forth in claim 3, wherein the metal silicide layer comprises tungsten silicide.

5. A process of producing a semiconductor device comprising the steps of:
forming a first amorphous silicon layer on a substrate;
forming a second amorphous silicon layer on the first amorphous silicon layer;
doping different conductivities of impurities at predetermined intervals into both the amorphous silicon layers;
applying a high temperature heat treatment to make the impurities diffuse into the amorphous silicon layers and crystallize the amorphous silicon layers to form polycrystalline silicon layers; and
forming one of a metal layer and metal silicide layer on the polycrystalline silicon layers.

6. A process of producing a semiconductor device as set forth in claim 5, wherein the polycrystalline silicon layers formed by the crystallization of the first and the second amorphous silicon layers comprise large grain polycrystalline silicon with a maximum crystal grain size of at least 200 nm.

7. A process of producing a semiconductor device as set forth in claim 5, wherein the first amorphous silicon layer and the second amorphous silicon layer are formed using the same chemical vapor deposition (CVD) system.

8. A process of producing a semiconductor device as set forth in claim 7, further comprising forming an interlayer film between the first amorphous silicon layer and the second amorphous silicon layer with a thickness in a range that allows electrical passage of electrons in the polycrystalline silicon layers by direct tunneling.

9. A process of producing a semiconductor device as set forth in claim 8, wherein the interlayer film comprises silicon oxide and the thickness is not more than 2 nm.

10. A process of producing a semiconductor device as set forth in claim 9, wherein the interlayer film is formed by oxidizing the surface of the first amorphous silicon layer by washing with at least one of mixed solutions selected from the group of a mixed solution of hydrogen peroxide and hydrofluoric acid, a mixed solution of hydrogen peroxide and sulfuric acid, a mixed solution of hydrogen peroxide and ammonia, and a mixed solution of hydrogen peroxide and hydrochloric acid.

11. A process of producing a semiconductor device as set forth in claim 9, wherein the interlayer film is formed by thermal oxidation of the surface of the first amorphous silicon layer.

12. A process of producing a semiconductor device as set forth in claim 9, wherein the interlayer film is formed by deposition of silicon oxide on the surface of the first amorphous silicon layer.

13. A process of producing a semiconductor device as set forth in claim 5, wherein the metal silicide layer comprises tungsten silicide.
